(19) United States
(12) Patent Application Publication
(10) Pub. No.: US 2004/0191502 A1
(43) Pub. Date: Sep. 30, 2004

(54) Hydrophilic surface composition and method

(76) Inventors: Michael William Howe, Spring, TX (US); Roderic Gernet Mathews, The Woodlands, TX (US)

Correspondence Address: Yukiko Iwata, Shell Oil Company, Legal-Intellectual Property, P.O. Box 2463, Houston, TX, 77252-2463, US

(21) Appl. No.: 10/808,936

(22) Filed: Mar. 25, 2004

Related U.S. Application Data
(60) Provisional application No. 60/457,410, filed on Mar. 25, 2003.

(51) Int. Cl. C30B 1/00

(52) U.S. Cl. 428/329; 428/323; 428/331

(57) ABSTRACT

An article that includes substrate and a coating of the reaction product of a metal oxide composition, a solvent and a surfactant. A method of making such an article that includes applying the reaction product of a metal oxide composition, a solvent, and a surfactant to a substrate; and drying the reaction product on the substrate to form a hydrophilic coating over at least a portion of the substrate. In some embodiments, the article is a window and the method is used to coat a window.

### CROSS REFERENCE TO RELATED APPLICATIONS

The present application claims the benefit of pending U.S. Provisional Patent Application Serial No. 60/457,410, filed Mar. 25, 2003, the entire disclosure of which is hereby incorporated by reference.

### FEDERALLY SPONSORED RESEARCH

Not applicable.

### REFERENCE TO MICROFICHE APPENDIX

Not applicable.

### FIELD OF THE INVENTION

The present invention is directed to the field of compositions for treating surfaces and methods thereof. In particular the present invention is directed at colloidal silica surface treatment compositions.

### BACKGROUND OF THE INVENTION

Surface treatments capable of imparting high hydrophilicity to a surface are desirable. A highly hydrophilic surface causes water to sheet rather than form beads. Sheeting is especially desirable when the surface is glass since the formation of water beads obstructs the view through the glass surface. In some cases, this obstruction merely reduces the aesthetic appeal of the surface as dissolved materials in each water bead deposit on the surface as the water dries. However, when the surface forms a window, the reduction in visibility is potentially dangerous, especially where the window is an automobile window.

Some methods and compositions for imparting relatively high hydrophilicity to a surface of a product have been described. Usually such compositions contain an inorganic compound that is formed into a film that also contains a photo-active semiconductor material. Organic substances are generally hydrophobic. Thus, when the photoactive semiconductor material is activated by ultraviolet light with a wavelength around 400 nm, the organic substances are decomposed. The decomposition can result in the surface of the photo-semiconductor material becoming hydrophilic. As a result, the contact angle of water to the surface of the coated film becomes low, and the surface of the coated film tends to wet easily. However, some amount of time is needed to develop the photocatalytic action of the photo-semiconductor material after it is irradiated with ultraviolet rays. Thus, the surface has an induction period during which it is not hydrophilic and tends to fog and stain. Also, the induction time may not be uniform over the entire surface since the development of the photocatalytic action of the semiconductor material is slower in regions where the irradiation intensity is lower. Additionally, compositions with a photoactive semiconductor are limited to the applications at which ultraviolet rays is easily applied. Thus, a composition capable of forming a hydrophilic surface that is simple and does not rely on a photoactive semiconductor would be useful in the art.

### SUMMARY OF THE INVENTION

Embodiments of the invention meet the above needs by providing an article, that includes a coating comprising a substrate and the reaction product of a metal oxide composition, a solvent, and a surfactant. Embodiments of the invention also provide methods for making such articles. Various embodiments are described as follows.

### BRIEF DESCRIPTION OF THE DRAWINGS

Not Applicable.

### DESCRIPTION OF EMBODIMENTS OF THE INVENTION

A surface treatment composition with a colloidal metal oxide, a solvent, and an optional surfactant is described. In some embodiments, the metal oxide is a colloidal silica and the solvent is an alcohol. Such compositions provide a durable hydrophillic film, especially when applied to glass. A method of making such compositions along with a method of treating a surface with these compositions are described.

In the following description, all numbers disclosed herein are approximate values, regardless whether the word “about” or “approximately” is used in connection therewith. They may vary by up to 1%, 2%, 5%, or sometimes 10 to 20%. Whenever a numerical range with a lower limit, R_{L}, and an upper limit R_{U}, is disclosed, any number R falling within the range is specifically disclosed. In particular, the following numbers R within the range are specifically disclosed: R=R_{L}+k*(R_{U}−R_{L}), wherein k is a variable ranging from 1% to 100% with a 1% increment, i.e. k is 1%, 2%, 3%, 4%, 5%, . . . , 50%, 51%, 52%, . . . , 95%, 96%, 97%, 98%, 99%, or 100%. Moreover, any numerical range defined by two numbers, R, as defined in the above is also specifically disclosed.

As used herein, the term “surfactant” refers to any substance that lowers the surface tension of a liquid, thereby allowing easier spreading or sheeting of the liquid. Surfactants generally contain both a water-soluble and a water-repelling portion. Surfactants are sometimes also referred to as wetting agents.

As used herein, the terms “colloid” and “colloidal” refer to mixtures in which the solute is present in the solvent primarily in the form of very small particles, rather than as single molecules or ions. Sometimes, the solute is referred to as the disperse phase and the solvent is referred to as the dispersion medium, or dispersant. In some embodiments, the disperse phase is solid and the dispersant is liquid. In such cases the colloid is known as a sol. In some other embodiments, the colloidal mixture the particles of the disperse phase link together with the dispersion medium circulating through the mixture. This type of colloid is called a gel.

The metal oxide composition of the surface treatment composition may be any metal oxide compound in which the metal is selected from any of Groups 3-10 metals and Group 13-15 metals and metalloids. In some embodiments, the metal oxide is silica, alumina or titania. In other embodiments, the metal oxide composition may contain two or more transition metals selected from Groups 3-12 and metals and metalloids of Groups 13-15 elements. Exemplary compositions of metal oxides having two or more such elements include Si₍₁₋ₓ₎AlₓO_{y}, where x ranges from 0 to 2 and y ranges from 2 to 3, Si₍₁₋ₓ₎TiₓO₂, where x can take any value from 0 to 1, and Al—Si—P—O compounds. In some embodiments where the metal oxide has two or more metals or metalloids, metal oxide compositions may also contain a metal from Groups 1-2 of the Periodic Table. In still other embodiments, the metal oxide composition is a combination of two or more individual metal oxides or metal oxide compositions. In some embodiments with two or more metal oxides, one metal oxide is silica and the second is titania or alumina. In other such embodiments, one metal oxide is alumina and the other is titania. Other combinations of metal oxides may also be useful.

The metal oxide composition may be supplied in any form. Sometimes the metal oxide composition is a powdered metal oxide composition. In other embodiments the metal oxide composition is supplied in the form of a colloidal dispersion. Examples of the colloidal dispersions include, but are not limited to, water-based colloidal dispersions and organic solvent-solvent-based colloidal dispersions. Generally, such colloidal dispersions contain one or more metal oxides in an amount of about 10 to about 50% by weight. In some embodiments, the dispersion has about 15, about 20, about 25, about 30, or about 35% by weight metal oxide composition. In other embodiments, the dispersion has about 40 or about 45% by weight metal oxide compositions.

Metal oxides in colloidal dispersions are known to have different activities. The activity of a metal oxide is a measure of the ability of the reactivity of the particles in the dispersion and is usually reported as a percent of the total metal oxide content. Some metal oxides have an activity of from about 5% to about 30% in embodiments of the dispersions described herein. In some embodiments, the activity is about 7%, about 10%, about 12% or about 15%. In other embodiments, the activity of the metal oxide is about 17%, about 20%, or about 25%.

In some embodiments, the metal oxide composition comprises particles that are substantially spherical. The term “substantially spherical” means, as used herein, that particles have an average aspect ratio of about 2.0 to about 0.5. Aspect ratio is defined herein as the ratio of the largest linear dimension of a particle to the smallest linear dimension of the particle. Aspect ratios may be determined from Scanning Electron Micrograph (SEM) images. Of course, this definition is intended to include spherical particles which by definition have an aspect ratio of 1.0. In some embodiments, the particle has a average aspect ratio of about 1.8, 1.6, 1.4, or 1.2. In other embodiments, the particle may have an average aspect ratio of 0.6 or 0.8. In still other embodiments, the metal oxide composition comprises particles that are not substantially spherical. Some particles that are not substantially spherical have a rod-like shape with an average width of about 20 to about 50 nm and a width of about 100 to about 600 nm. Some substantially spherical compositions have an average particle size of from about 5 to about 20 nm. However, compositions with an average particle size less than 5 nm or greater than 20 nm may also be used. In some embodiments, the average particle size of the metal oxide is about 7 nm, about 9 nm, or about 10 nm. In other embodiments, the average particle size is about 12 nm, about 15 nm, or about 18 nm.

For metal oxide compositions that are provided as a dispersion in an organic solvent, the organic solvent is not particularly limited. Examples of the organic solvents include substituted or unsubstituted aliphatic, aromatic or cyclic alcohols having from 1 to about 25 non-hydrogen atoms. In some embodiments, the alcohol is methanol, ethanol, isopropanol, or isobutanol. In some other embodiments, the solvent is 1-propanol, 2-propanol, 1-butanol, 2-butanol, 3-butanol, tert-butyl alcohol, a methyl butanol, a dimethyl butanol, 1-propanol, 2-propanol, 3-propanol, cyclohexanol, phenol, 2-ethylhexanol, 2-ethoxyethanol, 1-dodecanol, or mixtures thereof. Organic solvent dispersions of metal oxides, such as silica, can be easily prepared; however, commercially available are also suitable. Other solvents may also be useful depending on the various metal oxide compositions employed.

Whether the metal oxide is supplied as a powder or as a dispersion, it is mixed with a solvent or solvent mixture. Suitable solvents include water, ethylene glycol derivatives such as ethylene glycol, ethylene glycol monobutyl ether and ethylene glycol acetate monoethyl ether; diethylene glycol derivatives such as diethylene glycol and diethylene glycol monobutyl ether; and diacetone alcohol or the like. In some embodiments, the solvent is toluene, xylene, ethyl acetate, butyl acetate, methyl ethyl ketone, methyl isobutyl ketone, methyl ethyl ketoxime or the like may be used in combination of these solvents. One suitable solvent is a (mono) propylene glycol tertiary butyl ether commercially available as ARCOSOLV® PTB, CAS No. 57018-52-7. Another suitable solvent is propoxy propanol, commercially available as ARCOSOLV® PNP. Mixed solvent systems of these solvent and those enumerated in the preceding paragraph are also suitable, especially where a commercially prepared dispersion is employed.

The amount of solvent used in preparing compositions can vary. Generally, the amount of solvent used ranges from about greater than 80 percent by weight of the composition to about less than 100 percent by weight of the composition. In some embodiments, the solvent comprises about 85 percent by weight, about 90 percent by weight, about 95 percent by weight, or about 97.5 percent by weight of the composition. In other embodiments, the solvent comprises about 99.0 percent by weight, to about 99.2 percent by weight, about 99.4 percent by weight, or about 99.5 percent by weight. In some embodiments, the solvent comprises about 99.6 or about 99.7 percent by weight of the composition. In still other embodiments, the solvent may comprise a smaller or larger fraction of the total composition.

A variety of optional surfactants may also be useful in embodiments of the hydrophilic compositions herein. In some embodiments, the surfactant is an ethoxylated acetylenic alcohol, an ethylene oxide alkyl phenol, or an ethylene oxide alcohol. In other embodiments, the surfactant is a sodium laurel ether sulfate or a sodium sulfosuccinate. Ethoxylated amines and ethoxylated sorbitan esters are also useful in some compositions, as are block ethylene oxide/polyethylene oxide copolymers random ethylene oxide/polyethylene oxide copolymers. In some embodiments, other surfactants or mixtures of surfactants may also be used. Exemplary suitable surfactants are commercially available include Surfynol 61, Monawet MM 80, Hamposyl L-30, Igepal surfactants including Igepal CO-630 and Igepal CO-730, Zonyl FSO-100, Chemquatt-20 DES, and Q2-5211 silicone polyglycol available from Dow Corning.

The amount of surfactant used in preparing compositions that render a surface hydrophilic also varies. Generally, the surfactant comprises from about 0.01% by weight to about 1.0% of the composition. In some embodiments, the surfactant comprises about 0.05%, 0.10% or about 0.15% by weight of the composition. In other embodiments, the surfactant comprises about 0.20%, 0.30%, about 0.40%, or about 0.50% by weight of the surface treatment composition. In still other embodiments, the surfactant comprises about 0.70% or about 0.85% by weight of the surface treatment composition.

The components are generally mixed together in any order in forming the composition. In some embodiments, a reaction occurs upon mixing. However, in others, the composition comprises a substantially unreacted mixture of the components. After mixing, the composition can be applied to a surface, such as glass, by a variety of methods, including wiping or by spraying the composition onto the surface. After being applied to the surface, the composition is allowed to dry. In some embodiments, the composition is allowed to dry on the surface at atmospheric conditions. In other embodiments, a heat source may be use to dry the composition after it has been applied to the surface. In some embodiments, the components of the composition are transformed by a chemical reaction during either the mixing or the drying stages. In other embodiments, the components of the composition remain substantially unreacted during the mixing and drying stages. Thus, the components initially used in preparing the hydrophilic surface treatment composition may or may not be present in the film as it is formed on the treated surface.

After drying, the composition forms a transparent, hydrophilic film on the surface. The films preferably have a relatively high abrasion resistance when applied to a surface. Preferably, films are durable enough to withstand repeated abrasions of typical automobile windshield wipers. Abrasion resistance was measured by a modification of ASTM D-2486 using an AG-8100 Byk-Gardener Abrasion Tester with a reciprocating linear motion at 37.0±1 cycles per minute with a constant speed over a 10 inch travel. The drive mechanism of the abrasion testing apparatus consists of a gearhead motor driving the motor drive pulley gear. The rotary motion of this gear drives a smaller gear, the chain drive pulley, using a timing belt. The smaller gear drives a set of sprockets and continuous loop mechanism. The cable pair ends are attached to the virtual center of the chain, transforming the rotary motion of the chain into the reciprocating linear motion. Glass substrates were cut to fit the sample holder and treated with the compositions disclosed herein. An ordinary windshield wiper blade was attached to the apparatus to contact the glass at a wiper tension or pressure on the surface of approximately 1.5 oz/inch and operated in a manner simulating actual wiper operation. In operation, one back and forth motion of the wiper blade is considered a “wiper cycle.” In some embodiments, the compositions form a film that is durable enough to withstand 1000 to 5000 wiper cycles on a standard windshield. In other embodiments, the films withstand 5,000 to 7,500 cycles. Some films withstand 10,000, 20,000 or more cycles and retain suitable water sheeting properties. Of course, not all applications require such durability. Thus, some embodiments of films formed by the compositions described herein may be less durable.

The durability of films may also be assessed by measuring the film's hardness according to ASTM D 3363, incorporated herein by reference in its entirety. In this method, the hardness of various pencil leads is used to gauge the film hardness. Calibrated drawing leads vary in hardness having values of 6H, 5H, 4H, 3H, 2H, H, F, HB, B, 2B, 3B, 4B, 5B, and 6B, with 6H being the hardest. The difference between two adjacent leads is considered to be one unit of hardness. A coated surface is placed horizontally and a pencil is held firmly against the film at a 45° angle so that the pencil points away from the operator. The pencil is then pushed away from the operator in a 6.5 mm stroke. The process is started with the pencil having the hardest lead and continued with successively softer leads. The pencil hardness is defined as being the hardness of the first pencil in the series that does not cut into or gouge the film. Generally, films for testing according to ASTM D 3363 are dried at ambient conditions and have a thickness of greater than 0 nm to about 50 nm. In some embodiments, the lower limit of the range of film thickness ranges from 2 integrally to 10 nm or integrally from 2 to 50 nm. The upper limit on film thickness ranges integrally from about 4 nm to 100 nm in some embodiments. In some embodiments, the film has a thickness of about 100 nm, 200 nm, 500 nm, or 1 μm. Of course, thicker films may be used where desired. In some embodiments, the films have a hardness ranging from 2B to 6H. Particular embodiments have a hardness of B, HB, F, or H. Other embodiments have a pencil hardness of 5H, 4H, 3H, or 2H.

The hydrophilicity of the treated surface is determined by measuring the contact angle of water droplets on the surface according to ASTM D 5725-99. Generally, reagent water is used in such measurements. Suitable stroke lengths depend on the film composition and can be determined according to Procedure A of ASTM 5725-99. Generally, stroke lengths of from about 0.6 mm to about 2 mm are suitable. Where a surface is tested with more than one drop, the individual drops are separated by at least about 2 cm. In some embodiments, the average contact angles for films formed from the compositions described herein range from 0 to about 5 or to about 10 degrees. In some embodiments, the contact angle is about 0.5°, 1°, or 2°. The deviation of the samples from the average is generally about 10%. A lower contact angle is generally indicative of better sheeting action of the film.

### EXAMPLES

The following examples are given to illustrate various embodiments of the invention. They do not intend to limit the invention as otherwise described and claimed herein. All numerical values are approximate. When a numerical range is given, it should be understood that embodiments outside the range are still within the scope of the invention unless otherwise indicated. In the following examples, various polymers were characterized by a number of methods. Performance data of these polymers were also obtained. Most of the methods or tests were performed in accordance with an ASTM standard, if applicable, or known procedures.

Dispersion A is an isopropyl alcohol-based silica dispersion. The silica is present at a concentration of about 30 wt. % with a mean particle diameter of about 9 nm. The silica in the dispersion is about 30% active in the dispersion. One such silica dispersion is commercially available from Nissan Chemicals as the Snowtex-S dispersion.

Dispersion B is an isopropyl alcohol-based silica dispersion. The silica is present at a concentration of about 30 wt. % with a mean particle diameter of about 12 nm. The silica in the dispersion is about 30% active in the dispersion. One such silica dispersion is commercially available from Nissan Chemicals.

Dispersion C is a silica and alumina dispersion. The combined silica and alumina content is about 30 wt. % with particles having a mean particle diameter of about 12 nm. The particles in the dispersion have an activity of about 30% active in the dispersion. One such dispersion is Ludox® Cl commercially available from WR Grace.

Dispersion D is a water-based dispersion of silica particles coated with alumina. The silica/alumina particles comprise about 20 wt. % of the dispersion and have a mean particle diameter of about 12-14 nm. The particles are about 30% active in the dispersion. One such dispersion is commercially available from Nissan Chemicals under the trade name Snowtex-C. Dispersion E is an isopropyl alcohol-based dispersion of silica. The particles are about 15% active in the dispersion. One such dispersion is commercially available from Nissan Chemicals under the trade name Snowtex-XS.

Dispersion F is an isopropyl alcohol-based dispersion of silica. The silica comprises about 15.5 wt. % of the dispersion and has a chain-like morphology with particles being about 5-20 nm in width and 40-300 nm long. One such dispersion is commercially available from Nissan Chemicals under the trade name Snowtex-UP. Dispersion G is a dispersion of silica particles with an average particle diameter of about 13 nm that is commercially available as Clariant Highlink® OG-502-31.

### Examples 1-8

In Examples 1-8 various amounts of metal oxide dispersions are mixed with a solvent. Each resulting composition was applied to a glass plate and the quality and clarity of the film was assessed. The amounts of the components and the quality of the resulting films are recorded in Table I.

TABLE I

| | | | Water | |
|---|---|---|---|---|
| | | | Sheeting | |
| Example | Dispersion (wt. %) | Solvent (wt. %) | Ability | Clarity |
| 1 | A (0.5 wt. %) | ARCOsolv PNP/isopropyl alcohol | good | clear |
| | | (5.0 wt. %)/(94.5 percent) | | |
| 2 | B (0.5 wt. %) | ARCOSolv PTB./isopropyl alcohol | good | clear |
| | | (5.0 wt. %)/(94.5 wt. %) | | |
| 3 | A (0.5 wt. %) | ARCO solve PTB. (99.5 wt. %) | good | clear |
| 4 | B (0.5 wt. %) | isopropyl alcohol (99.5 wt. %) | Poor | Clear |
| 5 | A (0.33 wt. %) | isopropyl alcohol (99.67 wt. %)* | Good | Clear |
| 6 | A (0.33 wt. %) | 2-ethoxyethanol (99.67 wt. %) | Good | Clear |
| 7 | A (0.33 wt. %) | 2-ethoxyethanol/isopropyl alcohol | Poor | Poor |
| | | (10.00 wt. %)/(89.67 wt. %) | | |
| 8 | A (0.5 wt. %)/ | isopropyl alcohol/ | Poor | Good |
| | | NH₄OH | | |
| | | (99.0 wt. %)/ | | |
| | | (0.5 wt. % from concentrated | | |
| | | 29.6% in H₂O) | | |

*applied by aerosol using A.-85 propellant and a 0.18 inch M.B.A. nozzle

The results of experiments 1-8 indicate that good quality hydrophilic films can be obtained using a metal oxide and a solvent. Also, systems in which a metal oxide and a mixture of solvents are used also provide suitably transparent and hydrophilic films.

### Examples 9-39

In Examples 9-39 various amounts of metal oxide dispersions are mixed with a solvent and a surfactant. Each resulting composition was applied to a glass plate and the quality and clarity of the film was assessed. The amounts of the components and the quality of the resulting films are recorded in Table II.

TABLE II

| | | | | Water | |
|---|---|---|---|---|---|
| | | | | Sheeting | |
| Example | Dispersion (wt. %) | Surfactant (wt. %) | Solvent (wt. %) | Ability | Clarity |
| 9 | A (0.33 wt. %) | Surfynol 61 (0.10 wt. %) | methanol (99.57 wt. %) | Good | Good |
| 10 | A (0.33 wt. %) | Surfynol 61 (0.10 wt. %) | methanol (99.57 wt. %) | Good | Good |
| 11 | A (0.33 wt. %) | Surfynol 61 (0.10 wt. %) | isopropyl alcohol (99.57 wt. %) | Poor | Good |
| 12 | A (0.33 wt. %) | Surfynol 61 (0.10 wt. %) | n-propanol (99.57 wt. %) | Good | Good |
| 13 | A (0.33 wt. %) | Surfynol 61 (0.10 wt. %) | n-butyl alcohol (99.57 wt. %) | Good | Good |
| 14 | A (0.33 wt. %) | Surfynol 61 (0.10 wt. %) | Arcosolv PNP (99.57 wt. %) | Poor | Good |
| 15 | A (0.33 wt. %) | Surfynol 61 (0.10 wt. %) | Arcosolv TPB (99.57 wt. %) | Fair | Fair |
| 16 | A (0.33 wt. %) | Surfynol 61 (0.10 wt. %) | n-butyl alcohol/propylene glycol ether | Fair | Fair |
| | | | (69.70 wt. %/29.87 wt. %) | | |
| 17 | A (0.33 wt. %) | Surfynol 61 (0.10 wt. %) | 1-t-butoxy-2-propanol | Poor | Fair |
| | | | (99.57 wt. %) | | |
| 18 | A (0.33 wt. %) | Surfynol 61 (0.10 wt. %) | 1-t-butoxy-2-propanol | Good | Good |
| | | | (99.57 wt. %) | | |
| 19 | A (0.33 wt. %) | Surfynol 61 (0.10 wt. %) | n-propanol/ | Good | Good |
| | | | propylene glycol n-butyl ether | | |
| | | | (69.70 wt. %/29.87 wt. %) | | |
| 20 | A (0.33 wt. %) | Monawet MM 80 (0.15 wt. %) | n-propanol (99.52 wt. %) | Good | Good |
| 21 | A (0.33 wt. %) | Hamposyl L-30 (0.25 wt. %) | n-propanol (99.42 wt. %) | Fair | Fair |
| 22 | A (0.33 wt. %) | Igepal CO-210 (0.10 wt. %) | n-propanol (99.57 wt. %) | Good | Good |
| 23 | A (0.33 wt. %) | Chemquatt-20 DES (0.10 wt. %) | n-propanol (99.57 wt. %) | Fair | Fair |
| 24 | A (0.33 wt. %) | 0.10 wt. % Igepal CO-730 | n-propanol (99.57 wt. %) | Fair | Fair |
| 25 | A (0.33 wt. %) | 0.10 wt. % Igepal CO-630 | n-propanol (99.57 wt. %) | Good | Good |
| 26 | A (0.33 wt. %) | 0.05 wt. % Igepal CO-630 | n-propanol (99.62 wt. %) | Good | Good |
| 27 | A (0.33 wt. %) | 0.05 wt. % Zonyl FSO-100 | n-propanol (99.62 wt. %) | Good | Good |
| 28 | B (0.33 wt. %) | 0.05 wt. % Igepal CO-630 | n-propanol (99.62 wt. %) | Good | Good |
| 29 | C (0.33 wt. %) | 0.05 wt. % Igepal CO-630 | n-propanol (99.62 wt. %) | Good | Good |
| 30 | D (0.50 wt. %) | 0.05 wt. % Igepal CO-630 | n-propanol (99.62 wt. %) | Good | Fair |
| 31 | E (0.67 wt. %) | 0.05 wt. % Igepal CO-630 | n-propanol (99.28 wt. %) | Good | Good |
| 32 | A (0.33 wt. %) | 0.05 wt. % Igepal CO-630 | n-propanol/ | Good | Good |
| | | | (2-cyanoethyl) trimethoxysilane | | |
| | | | (99.52 wt. %/0.10 wt %) | | |
| 33 | A (0.33 wt. %) | 0.05 wt. % Igepal CO-630 | n-propanol/ | Fair | Fair |
| | | | Dynasylan AMMO | | |
| | | | (99.52 wt. %/0.10 wt %) | | |
| 34 | A (0.33 wt. %) | 0.05 wt. % Igepal CO-630/0.05 | n-propanol (99.57 wt. %) | Fair | Fair |
| | | wt % tetrabutyl titanate | | | |
| 35 | G (0.33 wt. %) | 0.05 wt. % Igepal CO-630 | n-propanol (99.62 wt. %) | Good | Good |
| 36 | A (0.33 wt. %) | 0.05 wt. % Dow Corning Q2- | n-propanol (99.62 wt. %) | Good | Good |
| | | 5211 silicone polyglycol | | | |
| 37 | A (0.33 wt. %) | 0.05 wt. % Igepal CO-630 | n-propanol/H₂O | Good | Good |
| | | | (94.62 wt. %/5 wt %) | | |
| 38 | F (0.66 wt. %) | 0.05 wt. % Igepal CO-630 | n-propanol/H₂O | Good | Fair |
| | | | (99.29 wt. %/5 wt %) | | |
| 39 | A (0.165 wt. %) | 0.05 wt. % Igepal CO-630 | n-propanol (99.62 wt. %) | Good | Good |
| | B (0.165 wt. %) | | | | |

As indicated by the data of Table II, a wide variety of compositions with a metal oxide dispersion, a solvent and a surfactant form hydrophilic films with good clarity. The durability of selected film was measured. In these measurements, the film composition was prepared and applied to a glass surface. The film was allowed to dry under ambient conditions. The durability of the resulting film and its ability to retain its hydrophilic character when used as a coating for windshields was tested using a Gardener-type wiper apparatus to simulate an automobile wiper system. After drying, distilled water was continuously applied while the wipers were in use. At various intervals the wipers were stopped and the film was visually inspected for wear. Table II records the film composition and the approximate number of wiper cycles before significant wear or loss of hydrophilicy of the surface was observed.

TABLE III

| Experiment | # of Cycles Before Wear |
|---|---|
| 26 | 3,000 |
| 28 | 2,000-3,000 |
| 29 | ˜8,000 |
| 30 | 7,000-8,000 |
| 31 | ˜10,000 |
| 32 | ˜10,000 |
| 34 | <1,000 |
| 35 | ˜15,000 |
| 36 | >10,000 |
| 38 | >10,000 |
| 39 | <7,000 |

As demonstrated above, embodiments of the invention provide a composition that forms a hydrophilic film for surface treatments. Some films are durable enough to withstand long periods of use as treatments for automobile windshields. Thus, these compositions and films made therefrom provide an alternative to present surface treatment compositions. Of course, numerous other products may be treated from the compositions described herein.

The surface treatment composition described herein have one or more of the following advantages. Some compositions have the beneficial quality that they are not substantially altered by prolonged continuous exposure or repeated intermittent exposure to moisture. Some compositions retain their hydrolphilic character after 5 to 10 or more hours of constant exposure. Some embodiments may simply be reapplied to worn or poorly hydrophilic areas that may develop over time; thereby, restoring the hydrophilic character to the surface using a minimum amount of the composition. In some embodiments, the surface treatment compositions are essentially transparent while in other embodiments, the composition is not. A non-transparent film may be desirable in conditions where the surface also acts to attenuate the amount of light passing through it.

While the invention has been described with respect to a limited number of embodiments, the specific features or advantages of one embodiment should not necessarily be attributed to other embodiments of the invention. No single embodiment is representative of all aspects of the inventions. In some embodiments, the compositions may include numerous compounds not mentioned herein. In other embodiments, the compositions do not include, or are substantially free of, any compounds not enumerated herein. Moreover, variations and modifications therefrom exist. For example, various additives, such as pigments, may also be used to further enhance one or more properties of the compositions and films made therefrom. It should also be understood that uses of the compositions are not limited to surface treatments, any product benefiting from a hydrophilic composition may be made. While the processes are described as comprising one or more steps, it should be understood that these steps may be practiced in any order or sequence unless otherwise indicated. These steps may be combined or separated. Also, while the disclosed products and processes are described as comprising various features, some embodiments of the invention consist essentially of the various features. In other embodiments, the products and processes consist of the enumerated elements. Finally, any number disclosed herein should be construed to mean approximate, regardless of whether the word “about” or “approximate” is used in describing the number. The appended claims intend to cover all such variations and modifications as falling within the scope of the invention.

We claim:

1. An article, comprising:
a) a coating comprising the reaction product of:
i) a metal oxide composition;
ii) a solvent; and
iii) a surfactant; and
b) a substrate.

2. The article of claim 1 wherein the metal of the metal oxide composition is selected from the group consisting of a transition metal of Groups 3-12 metal, a Group 13-15 metal or metalloid, and combinations thereof.

3. The article of claim 1 wherein the metal oxide composition is a dispersion selected from colloidal silica, alumina, and titania.

4. The article of claim 3 wherein the colloidal silica, alumina, or titania has a mean particle size ranging from about 5 to about 20 nm.

5. The article of claim 4 wherein the colloidal silica, alumina, or titania has a mean particle size of about 8 to about 10 nm.

6. The article of claim 3 wherein the dispersion has a dispersant selected from the group consisting of water and a substituted or unsubstituted aliphatic or aromatic cyclic alcohol having from 1 to about 25 non-hydrogen atoms.

7. The article of claim 6 wherein the alcohol is selected from the group consisting of methanol, ethanol, propanol, iso-propanol, 1-butanol, 2-butanol, tert-butyl alcohol, a methyl butanol, a dimethyl butanol, cyclohexanol, phenol, 2-ethyl hexanol, 1-dodecanol, and mixtures thereof.

8. The article of claim 1 further comprising a second metal oxide composition.

9. The article of claim 8 wherein the second metal oxide composition is alumina.

10. The article of claim 1 wherein the solvent is a substituted or unsubstituted aliphatic, aromatic or cyclic alcohol having from 1 to about 25 non-hydrogen atoms.

11. The article of claim 1 wherein the solvent is selected from the group consisting of water, a substituted or unsubstituted aliphatic, aromatic or cyclic alcohol having from 1 to about 25 non-hydrogen atoms, ethylene glycol, ethylene glycol monobutyl ether, ethylene glycol acetate monoethyl ether, diethylene glycol, diethylene glycol monobutyl ether, toluene, xylene, ethyl acetate, butyl acetate, methyl ethyl ketone, methyl isobutyl ketone, methyl ethyl ketoxime, mono propylene glycol tertiary butyl ether, propoxy propanol, and mixtures thereof.

12. The article of claim 1 wherein the surfactant is selected from the group consisting of ethoxylated acetylenic alcohols, sodium sulfosuccinate, ethylene oxide alkyl phenols, ethylene oxide alcohols, sodium laurel ether sulfate, block ethylene oxide/polyethylene oxide copolymer, an ethoxylated amine, ethoxylated sorbitan ester, random ethylene oxide/polyethylene oxide copolymers, and mixtures thereof.

13. The article of claim 1 wherein the coating has a pencil hardness ranging from about 4B to about 4H.

14. The article of claim 12, wherein the pencil hardness ranges from about 2B to about 2H.

15. The article of claim 1 wherein a water drop placed on the coating has a contact angle of 0 to about 10°.

16. The article of claim 15 wherein the contact angle 0 to about 2°.

17. The article of claim 1 wherein the substrate is a glass, plastic, metallic, stone or ceramic surface.

18. The article of claim 1 wherein the substrate is a window of a car, house, or door.

19. A method of making an article, comprising:
a) applying the reaction product of a metal oxide composition, a solvent, and a surfactant to a substrate; and
b) drying the reaction product on the substrate to form a hydrophilic coating over at least a portion of the substrate.

20. The method of claim 19 wherein the metal of the metal oxide composition is selected from the group consisting of a transition metal of Groups 3-12 metal, a Group 13-15 metal or metalloid, and combinations thereof.

21. The method of claim 19 wherein the metal oxide composition is a dispersion selected from colloidal silica, alumina, and titania.

22. The article of claim 21 wherein the colloidal silica, alumina, or titania has a mean particle size ranging from about 5 to about 20 nm.

23. The method of claim 22 wherein the colloidal silica, alumina, or titania has a mean particle size of about 8 to about 10 nm.

24. The method of claim 21 wherein the dispersion has a dispersant selected from the group consisting of water and a substituted or unsubstituted aliphatic or aromatic cyclic alcohol having from 1 to about 25 non-hydrogen atoms.

25. The method of claim 19 further comprising a second metal oxide composition.

26. The method of claim 25 wherein the second metal oxide composition is alumina.

27. The method of claim 19 wherein the solvent is a substituted or unsubstituted aliphatic, aromatic or cyclic alcohol having from 1 to about 25 non-hydrogen atoms.

28. The method of claim 19 wherein the solvent is selected from the group consisting of water, a substituted or unsubstituted aliphatic, aromatic or cyclic alcohol having from 1 to about 25 non-hydrogen atoms, ethylene glycol, ethylene glycol monobutyl ether, ethylene glycol acetate monoethyl ether, diethylene glycol, diethylene glycol monobutyl ether, toluene, xylene, ethyl acetate, butyl acetate, methyl ethyl ketone, methyl isobutyl ketone, methyl ethyl ketoxime, mono propylene glycol tertiary butyl ether, propoxy propanol, and mixtures thereof.

29. The method of claim 19 wherein the surfactant is selected from the group consisting of ethoxylated acetylenic alcohols, sodium sulfosuccinate, ethylene oxide alkyl phenols, ethylene oxide alcohols, sodium laurel ether sulfate, block ethylene oxide/polyethylene oxide copolymer, an ethoxylated amine, ethoxylated sorbitan ester, random ethylene oxide/polyethylene oxide copolymers, and mixtures thereof.

30. The method of claim 19 wherein the coating has a pencil hardness ranging from about 4B to about 4H.

31. The method of claim 30 wherein the pencil hardness ranges from about 2B to about 2H.

32. The method of claim 19 wherein a water drop placed on the coating has a contact angle of 0 to about 10°.

33. The method of claim 32 wherein the contact angle 0 to about 2°.

34. The article of claim 19 wherein the substrate is a glass, plastic, metallic, stone or ceramic surface.

35. The article of claim 19 wherein the substrate is a window of a car, house, or door.

36. An article, comprising:
a) a substrate; and
b) a hydrophilic coating on the substrate wherein the coating consists essentially of the reaction product of a metal oxide composition and a solvent.

37. The article of claim 36 wherein the metal of the metal oxide composition is selected from the group consisting of a transition metal of Groups 3-12 metal, a Group 13-15 metal or metalloid, and combinations thereof.

38. The article of claim 36 wherein the metal oxide composition is silica, alumina, titania, or combinations thereof.

39. The article of claim 37 wherein the metal oxide composition in the dispersion has a mean particle size ranging from about 5 to about 20 nm.

40. The article of claim 39 wherein the metal oxide composition has a mean particle size of about 8 to about 10 nm.

41. The article of claim 36 wherein the metal oxide composition comprises a metal oxide dispersion having a dispersant selected from the group consisting of water and a substituted or unsubstituted aliphatic or aromatic alcohol having from 1 to about 25 non-hydrogen atoms.

42. The article of claim 41 wherein the alcohol is selected from the group consisting of methanol, ethanol, propanol, iso-propanol, 1-butanol, 2-butanol, tert-butyl alcohol, a methyl butanol, a dimethyl butanol, cyclohexanol, phenol, 2-ethyl hexanol, 1-dodecanol, and mixtures thereof.

43. The article of claim 36 wherein the solvent is selected from the group consisting of water, a substituted or unsubstituted aliphatic, aromatic or cyclic alcohol having from 1 to about 25 non-hydrogen atoms, ethylene glycol, ethylene glycol monobutyl ether, ethylene glycol acetate monoethyl ether, diethylene glycol, diethylene glycol monobutyl ether, toluene, xylene, ethyl acetate, butyl acetate, methyl ethyl ketone, methyl isobutyl ketone, methyl ethyl ketoxime, mono propylene glycol tertiary butyl ether, propoxy propanol, and mixtures thereof.

44. The article of claim 36 further including a surfactant.

45. The article of claim 36 wherein the coating has a pencil hardness ranging from about 4B to about 4H.

46. The article of claim 45 wherein the pencil hardness ranges from about 2B to about 2H.

47. The article of claim 36 wherein a water drop placed on the coating has a contact angle of 0 to about 10°.

48. The article of claim 47 wherein the contact angle ranges from 0 to about 2°.

49. The article of claim 36 wherein the substrate is a glass, plastic, metallic, stone or ceramic surface.

50. The article of claim 36 wherein the substrate is a window of a car, house, or door.

51. The article of claim 50 wherein the window is a windshield of an automobile.

52. The article of claim 44 wherein the surfactant is selected from the group consisting of ethoxylated acetylenic alcohols, sodium sulfosuccinate, ethylene oxide alkyl phenols, ethylene oxide alcohols, sodium laurel ether sulfate, block ethylene oxide/polyethylene oxide copolymer, an ethoxylated amine, ethoxylated sorbitan ester, random ethylene oxide/polyethylene oxide copolymers, and mixtures thereof.

53. A method of making an article, comprising:
a) applying a composition consisting essentially of the reaction product of a metal oxide composition and a solvent to a substrate; and
b) drying the reaction product on to form a hydrophilic coating.

54. The method of claim 53 wherein the metal of the metal oxide composition is selected from the group consisting of a transition metal of Groups 3-12 metal, a Group 13-15 metal or metalloid, and combinations thereof.

55. The method of claim 53 wherein the metal oxide composition is silica, alumina, titania, or combinations thereof.

56. The method of claim 54 wherein the metal oxide composition in the dispersion has a mean particle size ranging from about 5 to about 20 nm.

57. The method of claim 56 wherein the metal oxide composition has a mean particle size of about 8 to about 10 nm.

58. The method of claim 53 wherein the metal oxide composition comprises a metal oxide dispersion having a dispersant selected from the group consisting of water and a substituted or unsubstituted aliphatic or aromatic alcohol having from 1 to about 25 non-hydrogen atoms.

59. The method of claim 58 wherein the alcohol is selected from the group consisting of methanol, ethanol, propanol, iso-propanol, 1-butanol, 2-butanol, tert-butyl alcohol, a methyl butanol, a dimethyl butanol, cyclohexanol, phenol, 2-ethyl hexanol, 1-dodecanol, and mixtures thereof.

60. The method of claim 53 wherein the solvent is selected from the group consisting of water, a substituted or unsubstituted aliphatic, aromatic or cyclic alcohol having from 1 to about 25 non-hydrogen atoms, ethylene glycol, ethylene, glycol monobutyl ether, ethylene glycol acetate monoethyl ether, diethylene glycol, diethylene glycol monobutyl ether, toluene, xylene, ethyl acetate, butyl acetate, methyl ethyl ketone, methyl isobutyl ketone, methyl ethyl ketoxime, mono propylene glycol tertiary butyl ether, propoxy propanol, and mixtures thereof.

61. The method of claim 53 further including a surfactant.

62. The method of claim 53 wherein the coating has a pencil hardness ranging from about 4B to about 4H.

63. The method of claim 63 wherein the pencil hardness ranges from about 2B to about 2H.

64. The method of claim 53 wherein a water drop placed on the coating has a contact angle of 0 to about 10°.

65. The method of claim 64 wherein the contact angle ranges from 0 to about 2°.

66. The method of claim 53 wherein the substrate is a glass, plastic, metallic, stone or ceramic surface.

67. The method of claim 53 wherein the substrate is a window of a car, house, or door.

68. The method of claim 67 wherein the window is a windshield of an automobile.

69. The method of claim 61 wherein the surfactant is selected from the group consisting of ethoxylated acetylenic alcohols, sodium sulfosuccinate, ethylene oxide alkyl phenols, ethylene oxide alcohols, sodium laurel ether sulfate, block ethylene oxide/polyethylene oxide copolymer, an ethoxylated amine, ethoxylated sorbitan ester, random ethylene oxide/polyethylene oxide copolymers, and mixtures thereof.
